(19) United States
(12) Patent Application Publication
(10) Pub. No.: US 2006/0263514 A1
(43) Pub. Date: Nov. 23, 2006

(54) Device and method for forming improved resist layer

(76) Inventor: Paul D. Shirley, Meridian, ID (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/497,140

(22) Filed: Aug. 1, 2006

Related U.S. Application Data
(63) Continuation of application No. 10/773,968, filed on Feb. 6, 2004.

(51) Int. Cl. B05D 3/12; C23C 16/52; B05C 11/00

(52) U.S. Cl. 427/8; 427/240; 118/52; 118/612; 118/666

(57) ABSTRACT

A device and method for improving the uniformity of resist layers. The device includes a rotatable substrate support, a resist supply, a control fluid supply and a controller. In operation, the placement of a control fluid is varied locally to promote a localized change in a rate of evaporation of the deposited resist to form a substantially uniform thickness of the deposited resist layer. The control fluid supply includes a pressure source, a conduit and a discharge orifice such that control fluid impinges onto a localized portion of the deposited resist such that thickness variations that would otherwise occur across portions of the deposited resist are avoided or minimized.

This application is a continuation of co-pending U.S. patent application Ser. No. 10/773,968, filed Feb. 6, 2004. The entire disclosure of that application is incorporated by reference.

### BACKGROUND OF THE INVENTION

The present invention relates generally to forming a uniform layer on a substrate, and more particularly to controlling environmental conditions during the formation of a resist layer to improve uniformity of the layer thickness.

Lithographic processes are extensively used in the manufacture of semiconductors and related electronic devices, where a layer of resist (also known as photoresist) is applied to a substrate to temporarily mask selected portions of the substrate, after which the resist is removed to permit subsequent substrate processing. Resist materials are generally composed of a mixture of organic resins, solvents and sensitizers. The resins make up the bulk of the finished resist, defining the body with various suitable mechanical properties. Solvents are added to lower the viscosity of the resist, thereby enabling a more uniform application of the resist onto the substrate. After the resist layer is formed, it is typically heated to evaporate the solvents and harden the layer. The sensitizers are configured to undergo a chemical change upon exposure to radiant energy, such as visible and ultraviolet light, thereby allowing the resist to cure into its final desired shape. The hardened resist layer is then selectively irradiated, where a reticle or related mask is used to define a predetermined circuit pattern.

One common method of applying the resist is by means of a spin coating process that typically takes place in a controllable environment, such as an enclosed (or at least partially enclosed) spin coat station. In such method, the resist in liquid form is deposited at the center of the substrate that is being spun around (such as a semiconductor wafer) to spread the resist outwardly by centrifugal force. In an ideal process, the thickness of the resulting resist layer is both uniform over the entire wafer and repeatable from wafer to wafer. Unfortunately, variations in environmental conditions, including (among others) airflow and humidity within the station, can be detrimental to the attainment of the aforementioned ideals, as the evaporation rate of solvents initially present in the resist exhibit considerable dependence on such environmental conditions. Because the solvent concentration is related to the resist viscosity and ultimately the thickness of the deposited resist layer, fluctuations in environmental conditions must be compensated for in order to improve uniformity in resist layer thickness.

### SUMMARY OF THE INVENTION

These needs are met by embodiments of the present invention where, according to a first aspect, a resist application device including a rotatable substrate support, a resist supply, a control fluid supply and a controller are disclosed. The controller is cooperative with the control fluid supply such that the control fluid supply varies the placement of the control fluid onto the deposited resist to effect a substantially uniform thickness layer thereof. The control fluid supply is configured to provide a localized change in a rate of evaporation of the deposited resist such that in operation, it facilitates the formation of a substantially uniform thickness of the deposited resist layer. The control fluid supply includes a pressure source, a conduit and a discharge orifice in fluid communication with the pressure source through the conduit, the discharge orifice configured to impart a control fluid onto a localized portion of the deposited resist. In the present context, a local change in evaporation rate is distinguished from that produced over the substantial entirety of the resist layer in that discrete (rather than global) thickness changes can be effected.

Optionally, the discharge orifice is a nozzle, which may be moveable in response to input from the controller. In another form, the control fluid supply can be made up of numerous fluid dispensing nozzles. One or both of a humidity supply and a temperature supply may additionally be included to effect their respective parameters adjacent the rotatable substrate support. The device may further include one or more sensors configured to sense at least one operational parameter associated with deposited resist. In one form, the sensor or sensors are signally coupled to the controller such that a deviation between a sensed operational parameter and a predetermined operational parameter is operated upon by the controller so that the controller varies the placement of the control fluid onto the deposited resist.

According to another aspect of the invention, a device configured to increase thickness uniformity of a layer of resist is disclosed. The device includes a supply configured to provide a flow of control fluid to a portion of the substrate that is susceptible to a thickness variation in the layer of resist. By application of the control fluid to the portion, the variation is reduced. A controller cooperative with the supply operates to vary the placement of the control fluid onto the deposited resist.

Optionally, the supply includes a pressure source, a conduit and a discharge orifice in fluid communication with the pressure source through the conduit. In one form, the supply includes numerous nozzles selectively responsive to the controller (for example, either selectively moveable or selectively in an “on” or “off” mode), while in another, a nozzle is moveably responsive to the controller to effect the variance in the placement of the control fluid onto the deposited resist. One or more sensors are used to detect one or more operational parameters associated with depositing the layer. As with the previous aspect, the nozzle can be made to move relative to the substrate in response to a deviation in the one or more operational parameters. The sensor may include an airflow sensor, humidity sensor and temperature sensor. The controller is configured to operate in at least one of a manual mode and an automated mode, where the manual mode is responsive to a user input, while the automated mode is responsive to one or more sensed operational parameters.

According to yet another aspect of the invention, a method of reducing thickness variations in a resist layer is disclosed. The method includes depositing resist onto a rotating substrate, configuring a control fluid supply device to deliver control fluid to the rotating substrate, and impinging the control fluid onto a portion of the deposited resist prior to curing of the resist to reduce thickness variations in the resist A controller is cooperative with a source of control fluid in the control fluid supply device such that upon input from the controller, the device varies the placement of the control fluid onto the deposited resist.

Optionally, the method includes sensing at least one operational parameter associated with the depositing of the resist, determining whether a deviation exists between the sensed operational parameter and a predetermined reference amount, and if the deviation exists, adjusting the operational parameter (or parameters) to reduce the deviation. The process may also include placing a housing around the rotating substrate to form a substantially controllable environment. The operational parameter may include control fluid flow rate, humidity within the housing and temperature within the housing. The method further includes moving the source of control fluid relative to the rotating substrate, thereby varying impingement of the control fluid onto a portion of the deposited resist prior to curing of the resist. The method may further include measuring a thickness of the deposited resist layer, determining if the thickness falls outside of a predetermined range, and adjusting (if necessary) the impingement of the control fluid onto the deposited resist to bring the measured thickness within the predetermined range. As previously discussed, the source may be made to comprise one or numerous nozzles. In the case of the latter, each nozzle may disposed over a different portion of the rotating substrate such that the curing characteristics of localized portions of the rotating substrate that correspond to each of the plurality of nozzles are adjusted independently of other such localized portions.

### BRIEF DESCRIPTION OF THE DRAWINGS

FIG. 1 is a sectional view of an undulated deposited resist layer on top of a wafer of the prior art where the resist layer is thicker at the outer periphery of the wafer;

FIG. 2 is a sectional view of an undulated deposited resist layer on top of a wafer of the prior art where the resist layer is thicker at the wafer center;

FIG. 3 is a sectional view of an undulated deposited resist layer on top of a wafer of the prior art where the resist layer is thicker at the wafer center and at the outer periphery of the wafer;

FIG. 4 is a sectional view of an undulated deposited resist layer on top of a wafer of the prior art where the resist layer is thicker at an intermediate position between the wafer center and the wafer outer periphery;

FIG. 5 is a schematic view of a resist application device according to an aspect of the present invention configured to avoid surface undulations in a deposited resist layer; and

FIG. 6 is a partial view of the device of FIG. 5, showing that a dispensing nozzle in the control fluid supply can be translated along a radial dimension of the wafer.

### DETAILED DESCRIPTION OF THE PREFERRED EMBODIMENTS

Referring first to FIGS. 1 through 4, environmental conditions around the spinning wafer W impact the viscosity of the resist and its consequent thickness once it is deposited on the wafer. For semiconductor applications, a resist layer thickness is typically between approximately 0.1 and 1 micron. The relative dimensions of the wafer W and the resist laye2 100, 300, 400 and 500 disposed thereon shown in the figures are not to scale, but meant to show general trends in non-uniform resist layers in their as-deposited state. Solvents are initially a part of the resist solution, and are included to promote solution flowability and related deposition properties. Upon deposition and exposure to the ambient environment (such as air) A around the wafer W, the solvents evaporate. By controlling the rate of evaporation of solvent from the resist R as it is being deposited, embodiments of the present invention promote improvements in resist layer thickness uniformity relative to that shown in FIGS. 1 through 4. Because viscosity is generally inversely proportional to the amount of solvent in the resist, the evaporation process (which has a strong influence over how much solvent remains in the resist), if extremely high, can inhibit the tendency of the resist to level out during subsequent layer deposition. This leads to surface undulations such as shown in FIGS. 1 through 4 where, depending on the processing and environmental conditions, differing thicknesses are produced at the resist layer center C from the periphery P and the intermediate I. For example, extremely high viscosities have a tendency to yield the dome-like pattern shown in FIG. 2, while extremely low viscosities have a tendency to yield the bowl-like shape of FIG. 1.

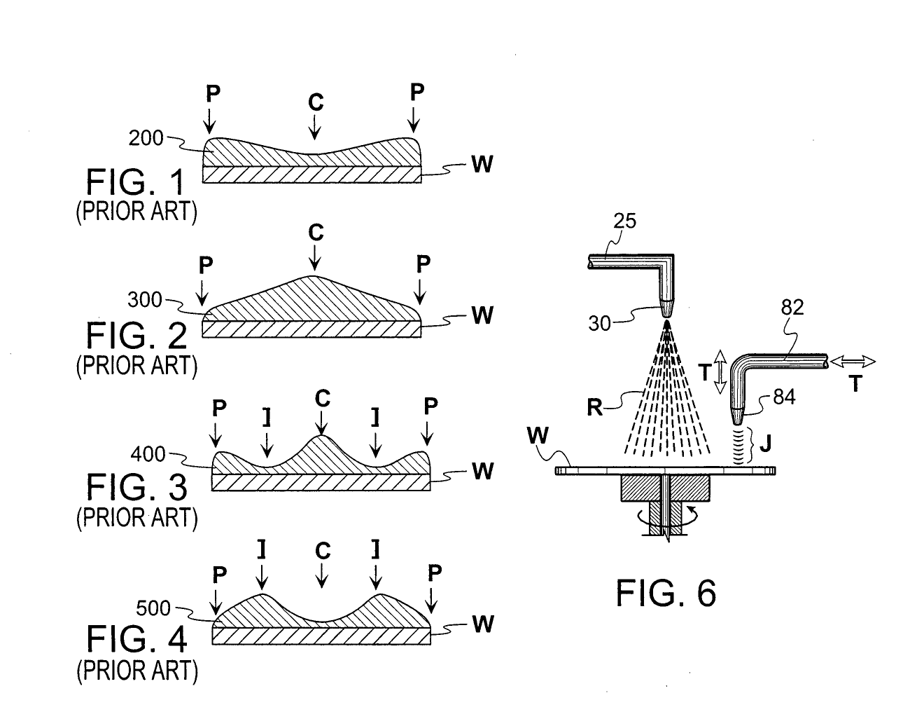

Other variables can be used to adjust the thickness on different parts of the wafer. For example, a higher pre-chill temperature of the wafer W tends to increase the resist thickness around the outer perimeter, typically within approximately one inch of the wafer W periphery on an eight inch diameter wafer. Test results indicate that a 1° C. temperature rise in the wafer W will raise the outermost part of the wafer W by ten to twenty Angstroms. Similarly, the higher the resist temperature, the higher the center (typically the innermost one to two inches on an eight inch wafer W) of the deposited resist becomes. Test results indicate that a 1° C. temperature increase will increase the thickness of the center by about ten Angstroms. Likewise, the higher the ambient environment A temperature, the higher the evaporation rate. The impact of higher air (or related environment) temperatures have the same general effect as the aforementioned pre-chill temperature. Regarding humidity, the higher it is, the lower the resist thickness. Test results indicate that a 1% change in relative humidity will change resist layer thickness by approximately twenty Angstroms. Another parameter, varying the “spin out” time of the wafer W, will yield different resist profiles, as shown in FIGS. 3 and 4, where the viscosity of the resist in combination with the spin speed of wafer W on the chuck can be parametrically combined to achieve a certain thickness in the resist layer at the center C, intermediate I or periphery P. Exhaust rates also have an impact on the outer periphery (such as the outer one inch) of wafer W, where the higher the exhaust, the higher the air flow, and the thicker the resist.

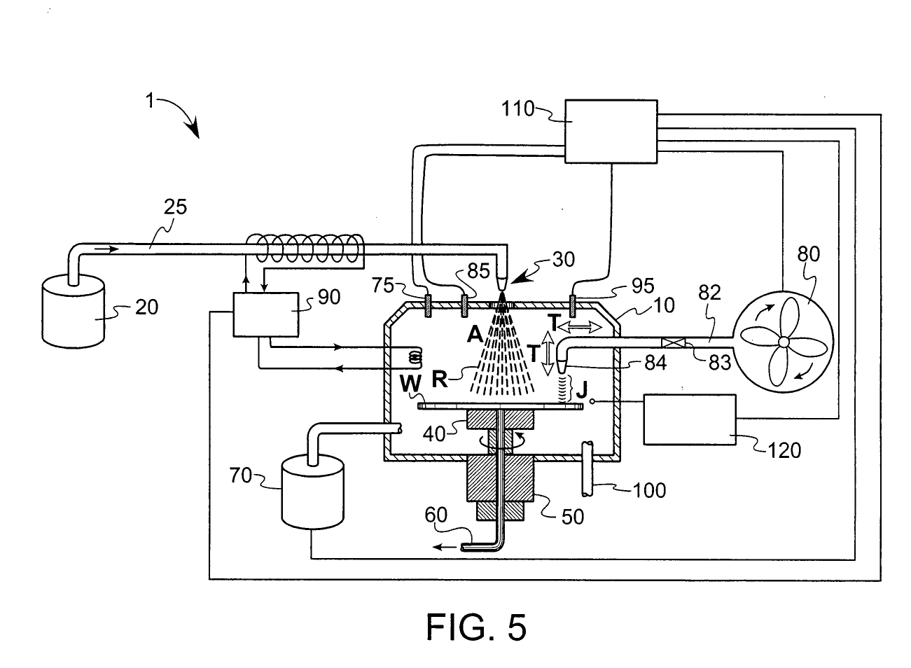

Referring next to FIG. 5, a resist application device 1 includes a housing 10 and resist supply 20 that terminates at dispensing nozzle 30 to dispense resist R. A support (in the form of a wafer chuck) 40 defines a generally planar a disc-like upper surface upon which a workpiece (such as a semiconductor wafer W) can be placed. Support 40 can be rotated about a generally vertical axis by motor 50. A vacuum 60 applied through the support 40 can be used to secure wafer W to support 40. It will be appreciated that the rotational speed of motor 50 can be adjusted to account for (by way of example) changes in resist viscosity during deposition or large wafers. For example, wafer chuck 40 can be rotated at a low starting speed (for example, 1000 rotations per second) and then rotated at a higher speed (for example, between 4000 and 6000 rotations per second) later on in the deposition process.

Housing 10 can at least partially enclose the support 40 to provide a substantially controllable environment inside. Environmental control inside housing 10 can be effected by a humidity supply 70, control fluid supply 80 and temperature supply 90, each of which is accompanied by at least one respective detector 75, 85 and 95 for measuring the corresponding environmental parameters. It will be appreciated that although the figures notionally show one of each type of detector, there can be numerous detectors of each type situated in various locations within housing 10. Examples of parameters that can be sensed include (but are not limited to) flow rates, temperature and humidity. In addition, drain/exhaust lines 100 pass through housing 10 to permit excess resist, airflow or the like to exit housing 10. Controller 110 coordinates the environmental activity within housing 10, and includes feedback circuitry to compare parameters sensed by detectors 75, 85 and 95 to a predetermined value and, if necessary, send a control signal to one or more of the respective humidity supply 70, control fluid supply 80 or temperature supply 90 to adjust the corresponding parameter. A layer thickness monitor 120 may be included to provide indicia of resist thickness as it is being deposited onto wafer W. As with the other sensed parameters, the information being sensed by the layer thickness monitor 120 can be fed back to controller 110 to permit manipulation of one or more of the humidity, airflow or temperature supplies. It will further be appreciated that the present invention need not even require the use of detectors 75, 85 and 95 during the resist layer deposition process, as data previously collected (during system setup, for example) could be used to dictate placement of nozzle 84, and what flow rate should be used. In this configuration, the relatively stable, robust nature of the setup and deposition process could be used to simplify the system by not requiring the real-time monitoring afforded by detectors 75, 85 and 95.

As previously mentioned, the thickness of the applied resist R is dependent upon (among other things) its viscosity, which is in turn dependent upon the amount of solvent in the resist R. The rate of solvent evaporation from the resist is dependent upon various environmental conditions (such as the airflow, humidity and temperature) within the ambient environment, and with housing 10 providing at least a partially controlled environment, the control fluid supply 80, humidity supply 70 and temperature supply 90, along with accompanying controller 110 can be used singly or in conjunction with one another to tailor the solvent evaporation rate in order to facilitate a desired resist thickness. Of the aforementioned environmental conditions, the inventor has determined that the introduction of local airflow J at discrete locations on the newly-deposited layer of resist R exerts a particularly strong influence on solvent evaporation and consequent resist layer thickness. This discrete, localized introduction of air (or other gases) can be used to offset the effects of inherent ambient atmospheric properties adjacent the deposited resist layer, where the rotating interface between the wafer W being coated and the ambient air A adjacent the wafer W that is inherent in spin coating devices produces relative airspeed differences between the outer periphery and the wafer center. Without the introduction of localized airflow according to the present invention to overcome them, these differences can contribute to uneven convective heat transfer and concomitant surface temperature variations and resist layer thickness. In addition, the higher airspeed at the periphery of a spinning wafer with resist deposited on it produces an increase in the thickness of the film due to the enhanced off-gassing of solvent and subsequent drying effect. Furthermore, the movement of ambient air A is used to carry away evaporated solvent, mist and particulate formation, the latter due to, among other things, the build-up and subsequent flaking off of resist that has spun off the wafer W and onto the wall of housing 10.

Control fluid flow from the control fluid supply 80 is provided to discrete locations on the surface of resist R deposited on wafer W, and can be used to vary the rate of evaporation of the deposited resist R. In one preferred form, air is the control fluid, although it will be appreciated that other control fluids can be used besides air. For example, substantially inert gases (such as argon, nitrogen or the like) could be used in situations where contaminants in the air, or the air's inherent reactivity due to its substantial oxygen presence, may preclude its use. A fan (as shown) or other airflow-inducing device (such as a compressor) can be used to generate a flow of air that is then routed through conduit 82 and discharged from nozzle 84. Valve 83 can be used to cut off airflow in response to an appropriate signal from controller 110. The control fluid J exits nozzle 84 in a more collimated, jet-like pattern than that of the relatively diffuse pattern of resist R exiting dispensing nozzle 30. Since the diameter of the area on wafer W that needs to be affected will generally be anywhere from approximately one half to two inches, an appropriate nozzle area should be no larger than approximately one half inch. By moving the nozzle 84 closer to or farther away from the surface (as shown by either or both horizontal and vertical translation T) defined by the deposited resist, corresponding larger or smaller portions of the resist layer can be bathed in the impinging control fluid. As an alternative (not shown), multiple nozzles 84 can be employed to increase or tailor area coverage. By maintaining the flow of control fluid J in a substantially coherent form, the efficacy of control fluid J is enhanced, as the flow of air or related fluid can more easily modify ambient atmosphere temperature, humidity or circulation conditions, and its placement on the uncured layer of resist R can be more precisely controlled. The use of a moving flow of control fluid J through movable nozzle 84 can be so effective that it could either augment or replace other environmental control devices, such as the aforementioned temperature and humidity supplies 90 and 70, respectively. Moreover, the airflow introduced can be used to cool select portions of the backside of wafer W to promote a more favorable temperature distribution.

Referring next to FIG. 6 in conjunction with FIG. 5, the ability of the nozzle 84 and a portion of conduit 82 of control fluid supply 80 to vary the placement of the control fluid J is shown. Since control fluid J is discharged from and deposited onto deposited layer of resist R in a relatively collimated flow, it impinges on the layer in discrete locations. By translating T the nozzle 84 relative to the spinning wafer W and layer of resist R disposed thereon, the device can compensate for otherwise unsatisfactory localized environmental conditions. For example, if it is required to reduce the thickness peaks at intermediates I of the layer 500 of FIG. 4, the nozzle 84 can be moved in proximity to the intermediates I to impart flow of control fluid J thereon. As previously discussed, nozzle 84 translation T can be in both horizontal and vertical directions as needed, and nozzle 84 can have its movement governed either automatically through controller 110 or by manual operation. An alternative approach (not shown) is to use a plurality of dispensing nozzles similar to nozzle 84 that can be arranged in an array or related configuration to achieve the same localized deposition as with the translating nozzle 84. In such a configuration, individual control valves (similar to valve 83) could be governed by controller 110 in response to sensed conditions within ambient air A to actuate a respective nozzle.

In another approach, the control fluid supply 80 and its ancillary components could be coupled with variations in the rotational speed of wafer chuck 40. Inclusion of controller 110 to coordinate control fluid flow and resist spin speed offers additional parametric control over the deposition and subsequent layer thickness formation of the resist on wafer W. In one form, detectors or sensors similar to those used to sense airflow, humidity and temperature parameters could be used as part of a feedback mechanism for real-time control, while in another, the motor 50 and control fluid supply 80 (including movement of nozzle 84 along one or both translational paths T) can be coordinated to produce a resist layer of the desired thickness.

Environmental humidity and temperature are additional conditions affecting the resist layer thickness. As a general rule, layer thickness increases with decreasing humidity, due to more rapid solvent evaporation. In the present system, controller 110 can also sense humidity or temperature changes during layer deposition, and can change one or more operational parameters to compensate. For example, gases (including solvent-containing gases) can be added to or removed from ambient air A to maintain a preferred humidity. The present system can be used to achieve humidity and temperature changes both locally (through the use of the aforementioned control fluid supply 80), as well as in the substantial entirety of the ambient atmosphere either within housing 10 or otherwise surrounding the deposited layer of resist R (through the use of the humidity supply 70 or temperature supply 90).

While the embodiments and systems discussed herein have been directed to a particular fill pattern, it is within the scope of the present invention to include similar simplistic, repeating arrangements to achieve the same end. Thus, having described the present invention in detail and by reference to the embodiments thereof, it will be apparent that modifications and variations are possible without departing from the scope of the invention in the following claims.

What is claimed is:

1. A resist application device comprising:
a rotatable substrate support;
a resist supply configured to deposit resist onto a substrate positioned on said support;
a control fluid supply configured to provide a localized change in a rate of evaporation of said deposited resist, said control fluid supply comprising:
a pressure source;
a conduit; and
a discharge orifice in fluid communication with said pressure source through said conduit, said discharge orifice configured to impart a control fluid onto a localized portion of said deposited resist; and
a controller cooperative with said control fluid supply such that said control fluid supply varies the placement of said control fluid onto said deposited resist to effect a substantially uniform thickness layer thereof.

2. The device of claim 1, wherein said discharge orifice comprises a nozzle.

3. The device of claim 2, wherein said nozzle is moveable in response to input from said controller.

4. The device of claim 3, wherein said control fluid supply comprises a plurality of fluid dispensing nozzles.

5. The device of claim 1, further comprising a humidity supply configured to humidify airspace adjacent said rotatable substrate support.

6. The device of claim 5, further comprising a temperature supply configured to adjust temperature adjacent said rotatable substrate support.

7. The device of claim 1, further comprising a temperature supply configured to adjust temperature adjacent said rotatable substrate support.

8. The device of claim 1, further comprising at least one sensor configured to sense at least one operational parameter associated with deposited resist, said at least one sensor signally coupled to said controller such that a deviation between a sensed at least one operational parameter and a predetermined operational parameter is operated upon by said controller so that said controller varies said placement of said control fluid onto said deposited resist.

9. A device configured to increase thickness uniformity of a layer of resist that has been deposited onto a substrate, said device comprising:
a supply configured to provide a flow of control fluid to a portion of said substrate that is susceptible to a thickness variation in said layer of resist such that upon application of said control fluid to said portion, said variation is reduced; and
a controller cooperative with said supply such that said supply varies the placement of said control fluid onto said deposited resist.

10. The device of claim 9, wherein said supply comprises a pressure source, a conduit and a discharge orifice in fluid communication with said pressure source through said conduit.

11. The device of claim 9, wherein said supply comprises a plurality of nozzles selectively responsive to said controller.

12. The device of claim 9, wherein said supply comprises a nozzle moveably responsive to said controller to effect said variance in the placement of said control fluid onto said deposited resist.

13. The device of claim 12, further comprising at least one sensor configured to sense at least one operational parameter associated with depositing said layer, said at least one sensor signally coupled to said controller such that said nozzle moves relative to said substrate in response to a deviation in said at least one operational parameter.

14. The device of claim 13, wherein said at least one sensor is selected from the group consisting of airflow sensor, humidity sensor and temperature sensor.

15. The device of claim 9, wherein said controller is configured to operate in at least one of a manual mode and an automated mode, said manual mode configured to be responsive to a user input and said automated mode configured to be responsive to at least one sensed operational parameter.

16. A method of reducing thickness variations in a resist layer, said method comprising:
depositing resist onto a rotating substrate;
configuring a control fluid supply device to comprise:
a source of control fluid configured to deliver said control fluid to said rotating substrate; and
a controller cooperative with said source such that upon input from said controller, said device varies the placement of said control fluid onto said deposited resist; and
impinging said control fluid onto a portion of said deposited resist prior to curing of said resist to reduce thickness variations thereof.

17. The method of claim 16, further comprising:
sensing at least one operational parameter associated with said depositing of said resist;
determining whether a deviation exists between said sensed at least one operational parameter and a predetermined reference amount; and
if said deviation exists, adjusting said at least one operational parameter to reduce said deviation.

18. The method of claim 17, including placing a housing around said rotating substrate to form a substantially controllable environment.

19. The method of claim 18, wherein said at least one operational parameter is selected from the group consisting of control fluid flow rate, humidity within said housing and temperature within said housing.

20. The method of claim 16, further comprising moving said source of control fluid relative to said rotating substrate, thereby varying impingement of said control fluid onto a portion of said deposited resist prior to curing of said resist.

21. The method of claim 16, further comprising:
measuring a thickness of said deposited resist layer;
determining if said thickness falls outside of a predetermined range; and if so
adjusting said impingement of said control fluid onto said deposited resist to bring said measured thickness within said predetermined range.

22. The method of claim 16, wherein said source comprises a plurality of nozzles each disposed over a different portion of said rotating substrate such that said curing characteristics of localized portions of said rotating substrate that correspond to each of said plurality of nozzles are adjusted independently of other such localized portions.
